(19) United States
(12) Patent Application Publication
(10) Pub. No.: US 2015/0060919 A1
(43) Pub. Date: Mar. 5, 2015

(54) COMPOSITE PARTICLE, METHOD OF PRODUCING SAME, RESIN COMPOSITION CONTAINING THE PARTICLE, REFLECTOR FORMED FROM THE COMPOSITION, AND LIGHT-EMITTING SEMICONDUCTOR DEVICE USING THE REFLECTOR

(71) Applicant: Shin-Etsu Chemical Co. Ltd., Chiyoda-ku (JP)

(72) Inventors: Toshio SHIOBARA, Annaka-shi (JP); Yoshihiro Tsutsumi, Annaka-shi (JP)

(73) Assignee: Shin-Etsu Chemical Co. Ltd., Chiyoda-ku (JP)

(21) Appl. No.: 14/453,251

(22) Filed: Aug. 6, 2014

(30) Foreign Application Priority Data
Aug. 28, 2013 (JP) 2013-176284

(51) Int. Cl. H01L 33/60; H01L 33/56; C08K 7/18; B28B 1/54; C08K 3/36; C08K 3/22

(52) U.S. Cl. CPC H01L 33/60; C08K 3/36; C08K 3/22; C08K 7/18; B28B 1/54; H01L 33/56; C08K 2003/2241
USPC 257/98; 524/588; 252/582; 241/3; 428/402; 65/21.2; 257/100

(57) ABSTRACT

A composite particle comprises inorganic compound particles that are derived from inorganic particle and are uniformly dispersed and sintered in a matrix phase composed of silica, or comprises silica particles that are uniformly dispersed and sintered in a matrix phase composed of said inorganic compound particles. The composite particle is prepared by sintering a mixture of (1) finely powdered silica having a BET specific surface area of 50 m²/g or greater, (2) an inorganic particle other than silica and (3) water at a temperature of 300° C. or higher to form a glass-like substance, and then crushing the glass-like substance. A spherical composite particle is prepared by melting and spheroidizing the mixture of (1)-(3) in a flame of 1,800° C. or higher. Also provided are a resin composition for a reflector for a light-emitting semiconductor device, a light-emitting semiconductor device that includes said reflector, and a light-emitting semiconductor device in which a light-emitting semiconductor element is encapsulated with said resin composition.

### BACKGROUND OF THE INVENTION

1. Field of the Invention

This invention relates to a reflector for a light-emitting semiconductor device that exhibits high light reflectance and is resistant to light transmission, a resin composition that is ideal for forming this reflector, and a composite particle that is added to the resin composition.

2. Description of the Related Art

Conventionally, reflectors for light-emitting semiconductor devices have typically been formed from compositions prepared by adding a white filler material such as titanium oxide, magnesium oxide or zinc oxide, and silica and the like to an epoxy resin or a silicone resin.

However, reflectors formed from a thermoplastic resin or an epoxy resin or the like have a problem in that, when a high-brightness LED or the like is installed, the resin degrades and yellows due to the effects of temperature and light (Patent Documents 1 and 2). Further, another problem arises because a large amount of a fine powder of titanium oxide or the like must be used to ensure a white color, and as a result, the flowability of the resin deteriorates, and when the reflector is molded by transfer or injection molding or the like, molding defects such as incomplete filling and voids tend to occur more frequently (Patent Document 3).

On the other hand, if a silicone resin is used, absolutely no discoloration of the reflector occurs even when a high-brightness LED is installed. However, if silica is used as a filler material, then a problem arises in that some of the emitted light escapes due to similar refractive index of silica to that of the silicone resin (Patent Document 4).

### CITATION LIST

### Patent Documents

Patent Document 1: JP 2006-140207 A
Patent Document 2: JP 2008-189833 A
Patent Document 3: JP 4,778,085 B
Patent Document 4: JP 2009-221393 A

### BRIEF SUMMARY OF THE INVENTION

Accordingly, an object of the invention is to provide a resin composition which is ideal for a reflector used in a light-emitting semiconductor device that exhibits high light reflectance and is resistant to light transmission, and to provide a composite particle that is added to the resin composition.

As a result of intensive investigation based on the above circumstances, the present inventors have found that by using a composite particle described below that comprises silica and a white inorganic particle such as titanium oxide, a resin composition that is suitable for preparing a reflector used in a light-emitting semiconductor device having a high light reflectance and a minimal light transmission could be obtained, and thus have completed the invention.

In other words, the invention is as described below.

<1> A composite particle prepared by sintering a mixture of (1) finely powdered silica having a BET specific surface area of 50 m²/g or greater, (2) an inorganic particle other than silica and (3) water at a temperature of 300° C. or higher to form a glass-like substance, and then crushing the glass-like substance, wherein said composite particle comprises inorganic compound particles that are derived from said inorganic particle and are uniformly dispersed and sintered in a matrix phase composed of silica, or alternatively said composite particle comprises silica particles that are uniformly dispersed and sintered in a matrix phase composed of said inorganic compound particles derived from said inorganic particles.
<2> A spherical composite particle prepared by melting and spheroidizing a mixture of (1) a finely powdered silica having a BET specific surface area of 50 m²/g or greater, (2) an inorganic particle other than silica and (3) water in a flame of 1,800° C. or higher, wherein said spherical composite particle comprises inorganic compound particles that are derived from said inorganic particle and are uniformly dispersed and sintered in a matrix phase composed of silica, or said composite particle comprises silica particles that are uniformly dispersed and sintered in a matrix phase composed of said inorganic compound particles derived from said inorganic particles.
<3> A method of producing a composite particle, the method comprising: sintering a mixture of (1) a finely powdered silica having a BET specific surface area of 50 m²/g or greater, (2) an inorganic particle other than silica and (3) water at a temperature of 300° C. or higher to form a glass-like substance, and then crushing the glass-like substance.
<4> A method of producing a spherical composite particle comprising silica and an inorganic compound particle derived from said inorganic particle and integrated with said silica, the method comprising: melting and spheroidizing a mixture of (1) a finely powdered silica having a BET specific surface area of 50 m²/g or greater, (2) an inorganic compound particle other than silica and (3) water in a flame of 1,800° C. or higher.
<5> A thermosetting resin composition comprising the composite particle described in <1> and a thermosetting resin.
<6> A thermosetting resin composition comprising the spherical composite particle described in <2> and a thermosetting resin.
<7> A reflector for a light-emitting semiconductor device, formed from the resin composition described in <5>.
<8> A reflector for a light-emitting semiconductor device, formed from the resin composition described in <6>.
<9> A light-emitting semiconductor device in which a light-emitting semiconductor element is installed on the reflector for a light-emitting semiconductor device described in <7>.
<10> A light-emitting semiconductor device in which a light-emitting semiconductor element is installed on the reflector for a light-emitting semiconductor device described in <8>.
<11> A light-emitting semiconductor device in which a light-emitting semiconductor element is encapsulated with the resin composition described in <5>.
<12> A light-emitting semiconductor device in which a light-emitting semiconductor element is encapsulated with the resin composition described in <6>.

According to this invention, provided are a resin composition which is ideal for a reflector used in a light-emitting semiconductor device that exhibits high light reflectance and is resistant to light transmission, as well as a composite particle that is added to the composition. Among composite particles, a spheroidized composite particle can be added to the resin composition in a large amount, and because the refractive index of the composite particle can be controlled freely by altering the blend ratio of the inorganic particle relative to silica, problems in terms of light loss and light reflection deficiencies can be solved.

### BRIEF DESCRIPTION OF THE DRAWINGS

FIG. 1 is an electron microprobe analyzer (EPMA) mapping diagram of the silicon (Si) in the composite oxide particle obtained in Example 1A.

FIG. 2 is an electron microprobe analyzer (EPMA) mapping diagram of the titanium (Ti) in the composite oxide particle obtained in Example 1A.

FIG. 3 is a series of diagrams illustrating a reflector of Example 6, wherein FIG. 3a illustrates a matrix type concave reflector substrate, FIG. 3b is a cross-sectional view of a device in which an LED element has been installed on an individual reflector substrate, and FIG. 3c is a plan view of the device shown in FIG. 3b.

### DETAILED DESCRIPTION OF THE INVENTION

The invention is described below in detail.

### [(1) Silica]

Representative examples of the finely powdered silica having a BET specific surface area of 50 m²/g or greater to be used in the invention include dry silica such as fumed silica obtained by spray combustion of silicon tetrachloride or a tetraalkoxysilane or the like at high temperature; precipitated silica obtained by reacting silicon tetrachloride or a tetraalkoxysilane with water and performing hydrolysis and condensation; and wet silica such as silica obtained by the sol-gel method. These finely powdered silica are preferable because they have a large surface areas.

Examples of commercially available finely powdered silica having a BET specific surface area of 50 m²/g or greater typically include fumed silica, including hydrophilic fumed silica such as Aerosil 90, Aerosil 130 and Aerosil 380 (trade names, manufactured by Nippon Aerosil Co., Ltd.), and hydrophobic fumed silica such as Aerosil R-972, Aerosil R-812 and Aerosil R-974 (trade names, manufactured by Nippon Aerosil Co., Ltd.) which are produced by chemically treating a hydrophilic fumed silica with an organosilicon compound such as a silane, a silazane or a siloxane. The specific surface area of the silica, which is typically reported as a specific surface area measured by the BET adsorption method, is 50 m²/g or greater, and may be as large as 100 to 400 m²/g. Further, the finely powdered silica having a BET specific surface area of 50 m²/g or greater is also typically referred to as nano silica, which has an average particle size of 0.1 μm (100 nm) or less, and in particular 0.001 to 0.05 μm (1 to 50 nm).

The average particle size herein can usually be determined as the cumulative weight-average value D₅₀ (or median value) in a particle size distribution measurement performed using a laser diffraction method.

[(2) Inorganic Particle Other than Silica]

Examples of the inorganic particle other than silica, that is used by mixing with the finely powdered silica having a BET specific surface area of 50 m²/g or greater, include finely powdered oxides, nitrides and the like. Specific examples of the inorganic particle other than silica include oxides such as titanium dioxide, zinc oxide, fumed alumina, magnesium oxide, and zirconium oxide; nitrides such as aluminum nitride and boron nitride, and the like. The inorganic particle preferably has an average particle size of 100 nm or less, more preferably 1 to 50 nm.

Examples of the titanium dioxide used herein include fine TiO₂ particles having an average particle size of approximately 25 nm, including the products sold under trade names CR50, CR80 and R820, that are manufactured by Ishihara Sangyo Kaisha, Ltd., the products sold under trade names R62N, GTR100, D918 and R39 that are manufactured by Sakai Chemical Industry Co., Ltd., and the product sold under trade name Aeroxide TiO₂ P25 manufactured by Nippon Aerosil Co., Ltd. Both the rutile type and anatase type titanium dioxides can be used. Further, examples of the zinc oxide include fine oxide powders having an average particle size of 25 nm or 35 nm, such as the products sold under trade names MZ-306× and MZ-506X that are manufactured by Tayca Corporation. An example of a fumed alumina (Al₂O₃) includes the product sold under trade name SpectrAl 100 manufactured by Cabot Corporation.

It is preferable that the compounds described above are mainly used as the inorganic particle other than the silica, but compounds other than oxides, such as hydroxides, may also be used in combination with the oxide(s), provided that they do not impair the effects of the invention.

### [Composite Particle]

The composite particle of the invention is a composite particle in which silica particle is integrated with an inorganic compound particle (that is derived from the aforementioned inorganic particle used as a raw material), especially a composite particle in which silica particle is integrated with a metal oxide particle. The aforementioned inorganic compound particle means a particle of an inorganic compound that is derived from the aforementioned inorganic particle used as a raw material during sintering a mixture of silica, the inorganic particle other than silica, and water at a temperature of 300° C. or higher. If the inorganic particle of the raw material is a nitride, the nitride can be altered at least partially to an oxide during sintering at a temperature of 300° C. or higher. The composite particle is, depending on blend ratios of silica and the inorganic particle of the raw material, either a powder of the inorganic compound particles uniformly dispersed and sintered in a matrix phase composed of silica, or is a powder of silica particles that are uniformly dispersed and sintered in a matrix phase composed of said inorganic compound particles. The composite particle generally has the silica (SiO₂) content of 10 to 99% by mass, preferably 20 to 90% by mass, and particularly preferably 30 to 80% by mass, and has a content of the inorganic compound particle other than silica (particularly metal oxides particle) of 1 to 90% by mass, preferably 20 to 90% by mass, and particularly preferably 30 to 80% by mass. Preferably, the composite particle is a composite oxide particle.

### [Method of Producing a Composite Particle]

The production of the composite particle of the invention can be accomplished by the following methods. For example, a finely powdered silica and an inorganic particle other than silica are mixed together uniformly in a high-speed mixer, and then a liquid such as water is added slowly until a gel-like substance is obtained. Subsequently, by placing finely powdered mixture of the gel-like substance in a heat-resistant container such as a ceramic container, and then performing a sintering treatment at a high temperature of at least 300° C., preferably 400° C. or higher, and more preferably 600° C. or higher, a uniform sintered product can be obtained. By crushing this sintered product to a fine powder using a crushing device such as a ball mill, a sintered composite particle powder containing inorganic compound particles uniformly dispersed in a matrix phase of silica (SiO₂), or a sintered composite particle powder containing silica (SiO₂) uniformly dispersed in a matrix phase consisting of the inorganic compound particle other than silica can be obtained.

### [Method of Producing a Spherical Composite Particle]

As aforestated, a method of producing a spherical composite particle comprises, for example, the steps of preparing a mixture by mixing a finely powdered silica having a BET specific surface area of 50 m²/g or greater, an inorganic particle other than silica, and water; preparing a gel-like substance by sintering the mixture at a temperature of 300° C. or higher; obtaining a composite particle by crushing the glass-like substance; and further melting and spheroidizing the composite particle in a flame at a high temperature, generally 1,800° C. or higher.

A simple method of producing a spherical composite particle comprises preparing a mixture by mixing a finely powdered silica having a BET specific surface area of 50 m²/g or greater, an inorganic particles other than the finely powdered silica, and water; preparing an agglomerated powder by removing water from the mixture using spray drying and the like, and melting and spheroidizing the agglomerated powder in a flame at a high temperature, e.g. 1,800° C. or higher. It is necessary to melt the agglomerated powder in a flame at 1,800° C. or higher for melting and spheroidization. This temperature is preferably 2,000° C. or higher.

The composite particle and spherical composite particle (hereafter also referred to as simply “the composite particle”) of the invention has a silica (SiO₂) content of 10 to 99% by mass, preferably 10 to 90% by mass, and particularly preferably 30 to 80% by mass, and has a content of an inorganic compound particles other than silica of 1 to 90% by mass, preferably 10 to 80% by mass, and particularly preferably 20 to 70% by mass. A silica content of 30 to 80% by mass is particularly desirable, as it yields a composite oxide having a good stability.

If the silica content is 10% by mass or less, then the binding effect with an inorganic phase of the other oxide(s), nitride(s) and the like becomes poor, whereas if the silica content exceeds 99% by mass, then the characteristic effects of the composite particle of the invention may not be attainable.

In terms of the particle size of the composite particle, when the composite particle is used as a filler material for an LED reflector material, the maximum particle size is preferably not more than 150 μm, and the average particle size is preferably from 5 to 30 μm. The maximum particle size is more preferably not more than 100 μm, and still more preferably 75 μm or less. The shape of the composite oxide particle is preferably spherical in terms of enabling a large amount of the particle to be included in the resin, but crushed shapes can also be used without any particular problems, provided that they satisfy the particle size range described above. Further, a combination of spherical particles and crushed particles may also be used. The average particle size can be determined as the cumulative weight-average value D₅₀ (or median value) in a particle size distribution measurement performed using a laser diffraction method.

### [Resin Composition]

Preferred examples of the resin to which the composite particle of the invention is added include, in the case where the invention is used as a reflector material, thermosetting resins such as epoxy resins, silicone resins, silicon-epoxy hybrid resins and cyanate resins; and thermoplastic resins such as polyphthalamides. Thermosetting silicone resins are particularly preferable. The thermosetting silicone resins include an addition-reaction curable silicone resin composition which includes a vinyl group-containing polyorganosiloxane and an organohydrogenpolysiloxanes. The silicone resin composition may also include additives such as curing catalysts, reaction inhibitors, release agents, adhesion aids and coupling agents, according to need.

The amount of the composite particle of the invention to be added to 100 parts by mass of the resin described above, is typically from 50 to 1,200 parts by mass, and preferably from 100 to 1,000 parts by mass. If the composite particle content is less than 50 parts by mass per 100 parts by mass of the resin, then optical properties, e.g. light reflectance and light transmittance required to use as a reflector material are not obtainable. If the composite particle content exceeds 1200 parts by mass, then the spiral flow value and melt viscosity required for molding are not obtainable.

When the resin composition of the invention is used as a reflector material, the reflector material may include, besides the aforementioned resin composition of the invention, conventional crystalline silica, fused silica, alumina, zinc oxide, zirconium oxide, glass fiber, carbon fiber, aluminum nitride, magnesium oxide, cristobalite, a coloring material and the like, provided that these other components do not impair the properties of the reflector.

The aforementioned conventional materials such as titanium oxide, aluminum, zinc oxide or carbon black can be used as a coloring material for the reflector. When a composite particle of the invention containing titanium oxide is used, there is no need to use separately a white pigment. However, if it is desirable to further increase the whiteness, then additional titanium oxide may be added as a separate component. The amount of the coloring material to be added is preferably from 0.5 to 20 parts by mass relative to 100 parts by mass for the resin.

When the composite particle of the invention is used as a filler material in an encapsulating agent (namely, used in an encapsulating resin composition) for a light-emitting semiconductor element, the composite particle is preferably used in an amount of 0.1 to 500 parts by mass, and preferably 0.5 to 300 parts by mass, relative to 100 parts by mass for the resin such as a transparent silicone resin, epoxy resin or silicone-epoxy hybrid resin.

The resin composition containing the composite particle of the invention must be as transparent as possible following curing, and therefore the refractive index of the composite particle is preferably similar to the refractive index of the cured resin. Accordingly, for the composite particle used as a filler material in the encapsulating agent, the refractive index is preferably adjusted by altering the proportion of the inorganic particles combined with the silica.

For example, when the composite particle is added to a silicone resin having a refractive index of approximately 1.53, a crushed and/or spherical finely powdered composite oxide prepared by uniformly mixing 100 parts by mass of a finely powdered silica and 100 parts by mass of a finely powdered alumina, and then performing sintering and/or melting in a flame is preferable in terms of the transparency and heat dissipation properties.

The aforementioned encapsulating resin composition may also include, besides the composite particle of the invention, a phosphor such as YAG and/or finely powdered alumina or silica for the purposes of thixotropy control.

An example of the method used for encapsulating the light-emitting semiconductor element includes a method which comprises dropwise pouring an encapsulating resin composition containing the composite particle of the invention, using a discharge device such as a dispenser, into the concave portion of a reflector having a light-emitting semiconductor element installed thereon, and then heating the composition at a temperature of 100° C. or greater for approximately 1 to 4 hours to cure the composition and complete the encapsulation.

### [Reflector for a Light-Emitting Semiconductor Device]

The reflector for a light-emitting semiconductor device according to the invention can be produced by molding the resin composition of the invention on a silver-plated copper lead frame by transfer molding or injection molding or the like.

### [Light-Emitting Semiconductor Device]

A light-emitting semiconductor device of the invention can be obtained by the method which comprises pouring dropwise the encapsulating resin composition containing the composite particle of the invention, using a discharge device such as a dispenser, into the concave portion of a reflector having a light-emitting semiconductor element installed thereon, and then heating the composition at a temperature of 100° C. or greater for approximately 1 to 4 hours to cure the composition and complete the encapsulation.

### EXAMPLES

The invention is specifically described below using a series of examples and comparative examples, but the invention is in no way limited by the examples presented below. The raw materials used were as follows.

(1) Hydrophilic fumed silica (SiO₂): manufactured by Nippon Aerosil Co., Ltd., trade name: Aerosil 380, BET specific surface area: approximately 380 m²/g.

(2) Hydrophobic fumed silica (SiO₂): manufactured by Nippon Aerosil Co., Ltd., trade name: Aerosil R-812, BET specific surface area: approximately 260 m²/g.

(3) Fumed mixed oxides (a physical mixture of silica and alumina, SiO₂/Al₂O₃): manufactured by Nippon Aerosil Co., Ltd., trade name: Aerosil MOX 84.

(4) Hydrophilic fumed metal oxide (TiO₂): manufactured by Nippon Aerosil Co., Ltd., trade name: Aeroxide TiO₂ P25.

(5) Hydrophilic fumed alumina (Al₂O₃): manufactured by Nippon Aerosil Co., Ltd., trade name: Aeroxide Alu C.

(6) Fumed alumina (Al₂O₃): manufactured by Cabot Corporation, trade name: SpectrAl 100.

(7) Titanium dioxide (TiO₂): manufactured by Ishihara Sangyo Kaisha, Ltd., trade name: CR-60.

### Example 1

As shown in Table 1, fumed silica (SiO₂) (Aerosil 380, manufactured by Nippon Aerosil Co., Ltd.), titanium dioxide (TiO₂) (CR-60, manufactured by Ishihara Sangyo Kaisha, Ltd.), fumed alumina (Al₂O₃) (SpectrAl 100 manufactured by Cabot Corporation) and water were mixed together using a mixing device until a uniform mixture was obtained, thus producing a series of clay-like mixtures. Each of these mixtures was placed in a muffle furnace at 400° C., 600° C. or 800° C. and heat-treated for 5 hours, and was then cooled to room temperature to obtain a sintered product.

TABLE 1

| | Raw | | | | |
|---|---|---|---|---|---|
| | material | | | | |
| | (units: | | | | |
| | parts | | | | |
| | by | Example | Example | Example | Example |
| Component | mass) | 1A | 1B | 1C | 1D |
| (1) | Silica | 50 | 70 | 30 | 70 |
| | (Aerosil | | | | |
| | 380) | | | | |
| (2) | CR-60 | 50 | | 30 | 20 |
| | (TiO₂) | | | | |
| | SpectrA1 | | 30 | 40 | 10 |
| | 100 | | | | |
| | (Al₂O₃) | | | | |
| (3) | Water | 10 | 10 | 10 | 10 |

| | |
|---|---|
| Evaluation results | |
| 400° C. | Partially insufficient sintered products |
| | exist |
| 600° C. | Vitrified |
| 800° C. | |

Following coarse crushing of the vitrified block produced by baking at 800° C. in each of Examples 1A to 1D, crushing was performed using a ball mill to produce crushed composite oxide particles (1A to 1D). Analysis of the state of distribution within these powdered particles revealed that the aluminum element and the titanium element existed in a uniform distribution. The particle size distribution of each of the crushed particles is shown below in Table 2. The particle size distribution was determined on a mass basis using a laser diffraction type particle size distribution analyzer (Microtrac HRA (X-100) manufactured by Nikkiso Co., Ltd.). The numerical values in Table 2 indicate mass % values.

TABLE 2

| | | Example | Example | Example | Example |
|---|---|---|---|---|---|
| Particle size | | 1A | 1B | 1C | 1D |
| greater than 150 | μm | 3 | 4 | 1 | 2 |
| 100 to 150 | μm | 12 | 16 | 8 | 5 |
| 75 to 100 | μm | 23 | 27 | 20 | 10 |
| 50 to 75 | μm | 35 | 23 | 31 | 20 |
| 30 to 50 | μm | 20 | 14 | 21 | 30 |
| 10 to 30 | μm | 6 | 10 | 11 | 21 |
| 1 to 10 | μm | 1 | 5 | 7 | 10 |
| less than 1 | μm | 0 | 1 | 1 | 2 |

### Comparative Example 1

Fifty parts by mass of fumed silica (SiO₂) (Aerosil 380, manufactured by Nippon Aerosil Co., Ltd.), 50 parts by mass of titanium dioxide (TiO₂) (CR-60, manufactured by Ishihara Sangyo Kaisha, Ltd.) and 10 parts by mass of water were mixed together using a mixing device until a uniform mixture was obtained, thus producing a clay-like mixture. This mixture was placed in a muffle furnace at 200° C. and heat-treated for 5 hours, and was then cooled to room temperature. The obtained product was not sintered at all, and was merely a powder that could easily be broken up by rubbing with hand.

### Example 2

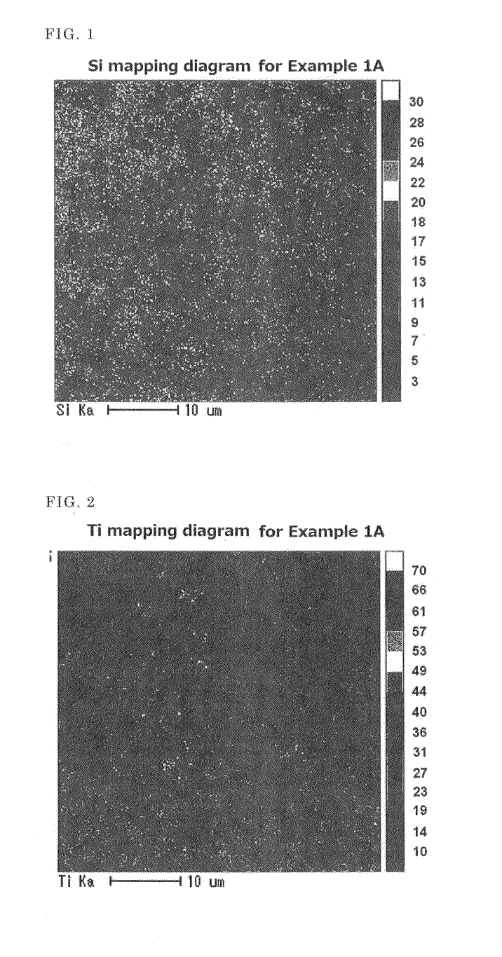

Each of the composite oxides obtained by baking at 400° C. in Examples 1A to 1D was crushed in a ball mill until a fine powder was obtained, and the crushed powder was then regulated using a sieve to obtain a particle size of 50 μm or less. Each of these powders was melted by sprinkling onto a flame at 2,000° C., and was then cooled, thereby producing a series of spherical composite oxides 2A to 2D. Each of these composite oxides was composed of particles having a spherical shape and a uniform composition distribution. The particle size distribution of each composite oxide is shown in Table 5. The numerical values in Table 5 indicate mass % values. In Example 1A, electron microprobe analyzer (EPMA) mapping diagrams of the silicon (Si) and the titanium (Ti) in the composite oxide obtained by baking at 400° C. are shown in FIG. 1 and FIG. 2, respectively.

TABLE 3

| | | Example | Example | Example | Example |
|---|---|---|---|---|---|
| Particle size | | 2A | 2B | 2C | 2D |
| greater than 100 | μm | 1 | 0 | 1 | 0 |
| 75 to 100 | μm | 12 | 8 | 9 | 4 |
| 50 to 75 | μm | 20 | 12 | 15 | 15 |
| 30 to 50 | μm | 25 | 35 | 26 | 21 |
| 10 to 30 | μm | 20 | 25 | 25 | 30 |
| 1 to 10 | μm | 17 | 17 | 20 | 23 |
| less than 1 | μm | 5 | 3 | 4 | 7 |

### Example 3

Raw materials (mixed fine powders) having a blend ratio shown in Table 4 were granulated in the presence of a small amount of water using a granulator. Each of the obtained granular powders was melted by sprinkling onto a flame at 2,000° C., thus producing a series of spherical composite oxide particles 3A to 3D. The particle size distribution of each of the obtained composite particles is shown in Table 5.

TABLE 4

| | Raw | | | | |
|---|---|---|---|---|---|
| | material | | | | |
| | (units: | | | | |
| | parts | Example | Example | Example | Example |
| Component | by mass) | 3A | 3B | 3C | 3D |
| (1) | Silica | 50 | 70 | 70 | 70 |
| | (Aerosil | | | | |
| | 380) | | | | |
| (2) | Aeroxide | 50 | | 20 | 20 |
| | TiO₂ P25 | | | | |
| | (TiO₂) | | | | |
| | Aeroxide | | 30 | 10 | 10 |
| | Alu C | | | | |
| | (Al₂O₃) | | | | |
| (3) | Water | 2 | 2 | 2 | 10 |

TABLE 5

| | | Example | Example | Example | Example |
|---|---|---|---|---|---|
| Particle size | | 3A | 3B | 3C | 3D |
| greater than 150 | μm | 1 | 0 | 2 | 0 |
| 100 to 150 | μm | 3 | 2 | 5 | 2 |
| 75 to 100 | μm | 11 | 14 | 18 | 7 |
| 50 to 75 | μm | 31 | 34 | 36 | 21 |
| 30 to 50 | μm | 21 | 21 | 21 | 30 |
| 10 to 30 | μm | 17 | 15 | 12 | 25 |
| 1 to 10 | μm | 11 | 11 | 5 | 12 |
| less than 1 | μm | 5 | 3 | 1 | 3 |

### (A) Vinyl Group-Containing Organopolysiloxane

### Synthesis Example 1

One thousand gram of xylene and 5014 g of water were placed in a flask, and a mixture containing 2285 g (10.8 mol) of phenyltrichlorosilane, 326 g (2.70 mol) of dimethylvinylchlorosilane and 1478 g of xylene was added dropwise to the flask. After dropwise addition, stirring was performed for 3 hours, a waste acid was separated and washing with water was performed. After azeotropic dewatering, 6 g (0.15 mol) of KOH was added, and heating for reflux was performed at 150° C. overnight. Twenty seven gram (0.25 mol) of trimethylchlorosilane was added to an obtained product, neutralization with 24.5 g (0.25 mol) of potassium acetate and then filtration were performed. Subsequently, solvents were distillated away under vacuum, and a siloxane resin (A-1) represented by an average formula (I) shown below was synthesized in the form of a colorless and transparent solid at room temperature. The vinyl equivalent was 0.0013 mol/g, and content of hydroxyl group was 0.01% by mass. The softening point was 65° C.

(C₆H₅SiO_{3/2})_{0.80}((CH₂═CH)(CH₃)₂SiO_{1/2})_{0.20} (1)

### (B) Cross-Linking Agent Having Si—H

An organohydrogenpolysiloxane represented by the structural formula shown below was used as a cross-linking agent.

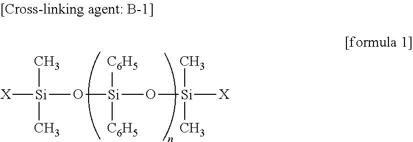

Hydrogen yield: 0.00377 mol/g

n=2.0 (mean value), X: hydrogen atom, Si—H group equivalent: 0.403.

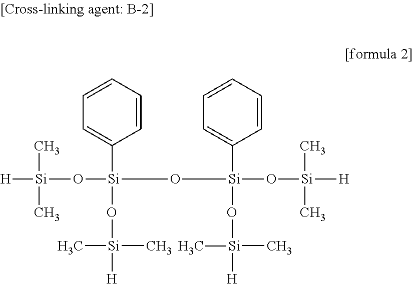 [SMILES: C[SiH](C)O[Si](O[SiH](C)C)(O[Si](O[SiH](C)C)(O[SiH](C)C)c1ccccc1)c1ccccc1]

Hydrogen yield: 0.0076 mol/g

### (C) Addition Reaction Catalyst

An octyl alcohol-modified solution containing a chloroplatinic acid (platinum concentration: 2% by mass)

### (D) Adhesion Aid

An organohydrogenpolysiloxane represented by the structural formula shown below was used as an adhesion aid.

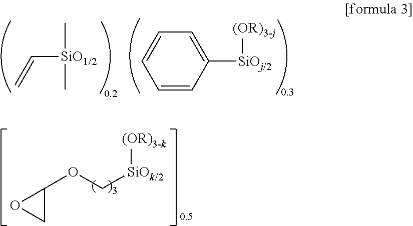

(wherein, j and k are independently 1, 2 or 3, R is independently hydrogen atom, methyl group or isopropyl group, a polystyrene conversion weight-average molecular weight measured by GPC is 3045.)

### (E) Reaction Inhibitor

### 3-methyl-tridecyn-3-ol

### (F) Release Agent

Rikester EW 440A: manufactured by RIKEN VITAMIN Co., Ltd.

### Example 4

Ninety four parts by mass of the vinyl group-containing silicone (A) produced in Synthesis Example 1, 4 parts by mass of the cross-linking agent (B-1), 17 parts by mass of the cross-linking agent (B-2), 0.1 parts by mass of the addition reaction catalyst (C), 6.2 parts by mass of the adhesion aid (D), 6.5 parts by mass of the reaction inhibitor (E), 0.7 parts by mass of the release agent (F), and 580 parts by mass of the composite oxide (G) produced in Example 3A were subjected to preliminary mixing, and were then kneaded using a continuous kneading device, thus producing a white thermosetting silicone resin composition.

### Comparative Example 2

Ninety four parts by mass of the vinyl group-containing silicone (A) produced in Synthesis Example 1, 4 parts by mass of the cross-linking agent (B-1), 17 parts by mass of the cross-linking agent (B-2), 0.1 parts by mass of the addition reaction catalyst (C), 6.2 parts by mass of the adhesion aid (D), 6.5 parts by mass of the reaction inhibitor (E), 0.7 parts by mass of the release agent (F), 460 parts by mass of a fused spherical silica having an average particle size of 13 μm (G′-1), and 115 parts by mass of titanium dioxide (G′-2) were kneaded using a continuous kneading device, thus producing a white thermosetting silicone resin composition.

For each of the compositions of Example 4 and Comparative Example 2, the properties described below were measured. The results are shown in Table 6. Molding was all performed using a transfer molding machine.

### <Spiral Flow Value>

Using a molding die prescribed in the EMMI standards, a spiral flow value was measured under conditions including a molding temperature of 150° C., a molding pressure of 6.9 N/mm², and a molding time of 180 seconds.

### <Melt Viscosity>

Using a Koka-type flow tester and a nozzle with a diameter of 1 mm, a viscosity at a temperature of 150° C. was measured under a pressure of 10 kgf.

### <Flexural Strength and Flexural Modulus>

A test piece prepared by using a molding die prescribed in the JIS-K6911 standard to perform molding under conditions including a molding temperature of 150° C., a molding pressure of 6.9 N/mm² and a molding time of 180 seconds, and then post-curing at 150° C. for 4 hours, was measured for flexural strength and flexural modulus at room temperature.

### <Light Reflectance and Light Transmittance>

A square-shaped cured product having a length along one side of 50 mm and a thickness of 0.35 mm was prepared under conditions including a molding temperature of 150° C., a molding pressure of 6.9 N/mm² and a molding time of 180 seconds, and the light reflectance and light transmittance at 450 nm were measured using an X-rite 8200 manufactured by S.D.G K.K.

TABLE 6

| | | | Comparative |
|---|---|---|---|
| Evaluation | Unit | Example 4 | Example 2 |
| Spiral flow | Inch | 35 | 38 |
| Melt viscosity | Pa · s | 25 | 26 |
| Flexural strength | MPa | 55 | 56 |
| Flexural modulus | MPa | 7,800 | 8,400 |
| 450 nm light reflectance | % | 97 | 94 |
| 450 nm light | % | 0.3 | 2.5 |
| transmittance | | | |

From the results in Table 6, it is evident that by using the composite particle produced by the invention, the cured product of the resin composition containing said composite particle can exhibit improved optical properties, and particularly light transmittance, while retaining the other properties such as mechanical strength.

### Example 5 CL Molding of Reflector and Physical Properties Thereof

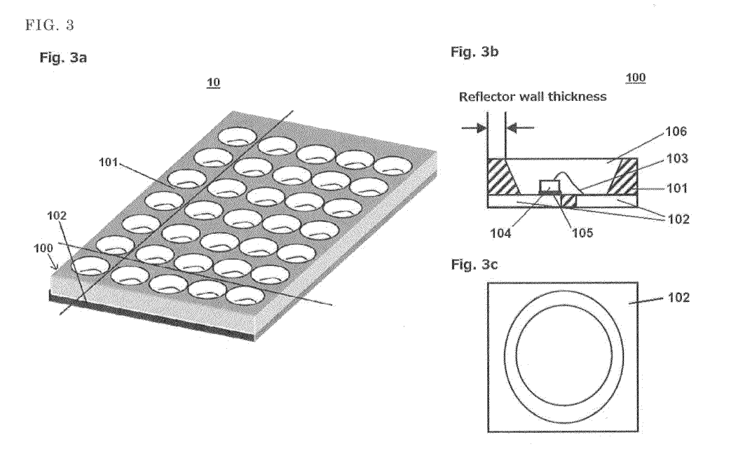

Using the resin compositions produced in Example 4 and Comparative Example 2, and a totally silver-plated copper lead frame 102, a matrix type concave reflector 10 illustrated in FIG. 3 was prepared by transfer molding (by molding the encapsulating resin composition to have a thickness of 1 mm, a length of 38 mm and a width of 16 mm on top of the silver surface plated copper substrate) under the following molding conditions.

The molding conditions were as follows.

Molding temperature: 150° C.

Molding pressure: 70 kg/cm²

Molding time: 3 minutes

Post curing was also performed at 150° C. for 4 hours.

### <Warping Measurement>

Warping was measured in two diagonal directions on the resin surface side of the post-cured molded reflector having the shape described above, and the average of these two values was recorded. The results revealed a warping value of 210 μm for the resin composition produced in Example 4, and a warping value of 560 μm for the resin composition produced in Comparative Example 2, confirming that use of the composite oxide particle of the invention is also effective in yielding superior warping properties for the molded products of the resin compositions.

### Example 6

A blue LED element 104 was bonded, using a silicone die bonding agent 105 (product name: LPS632D, manufactured by Shin-Etsu Chemical Co., Ltd.), to a portion of the lead frame 102 exposed within the concave bottom of each reflector 100 in the matrix type reflectors 10 molded using the resin composition of Example 4 or Comparative Example 2, and the LED element electrode was connected electrically to another lead portion using a gold wire 103. Subsequently, a silicone encapsulating agent (LPS380, manufactured by Shin-Etsu Chemical Co., Ltd.) 106 was injected into the concave opening in which the LED element 104 had been positioned, and curing was performed at 120° C. for 1 hour and then at 150° C. for 1 hour to encapsulate the LED element 104.

The matrix type reflector was then divided into individual devices by dicing. Using five of these individual LED devices assembled from a reflector produced by molding the resin composition of Example 4 or Comparative Example 2, the brightness was measured using a CS-2000A device manufactured by Konica Minolta, Inc. When the brightness of the LED which used the reflector molded from the resin composition of Example 4 was deemed to be 100, the brightness of the LED prepared from the resin composition of Comparative example 2 dropped to a value of 93. Further, when the lit LED was observed from the side of the LED package, the device produced using the reflector produced from the resin composition of Comparative Example 2 exhibited light leakage.

### DESCRIPTION OF THE REFERENCE SIGNS

10: Concave reflector substrate
100: Divided individual concave reflector substrate
101: Resin composition
102: Lead frame
103: Gold wire
104: LED element
105: Die bonding agent
106: Transparent encapsulating resin

What is claimed is:

1. A composite particle prepared by sintering a mixture of (1) finely powdered silica having a BET specific surface area of 50 m²/g or greater, (2) an inorganic particle other than silica and (3) water at a temperature of 300° C. or higher to form a glass-like substance, and then crushing the glass-like substance, wherein said composite particle comprises inorganic compound particles that are derived from said inorganic particle and are uniformly dispersed and sintered in a matrix phase composed of silica, or comprises silica particles that are uniformly dispersed and sintered in a matrix phase composed of said inorganic compound particles derived from said inorganic particles.

2. The composite particle according to claim 1, wherein the inorganic particle other than silica is one or more inorganic materials selected from among metal oxide particle and nitride particle with a particle size of 10 μm or less.

3. The composite particle according to claim 2, wherein the inorganic particle other than silica is one or more inorganic materials selected from among titanium dioxide, magnesium oxide, zinc oxide, alumina and aluminum nitride.

4. A spherical composite particle prepared by melting and spheroidizing a mixture of (1) a finely powdered silica having a BET specific surface area of 50 m²/g or greater, (2) an inorganic particle other than silica and (3) water in a flame of 1,800° C. or higher, wherein said spherical composite particle comprises inorganic compound particles that are derived from said inorganic particle and are uniformly dispersed and sintered in a matrix phase composed of silica, or comprises silica particles that are uniformly dispersed and sintered in a matrix phase composed of said inorganic compound particles derived from said inorganic particles.

5. The spherical composite particle according to claim 4, wherein the spherical composite particle is produced, prior to the melting in a flame, by sintering the mixture at a temperature of 300° C. or higher to form a glass-like substance, and then crushing the glass-like substance.

6. The composite particle according to claim 4, wherein the inorganic particle other than silica is one or more inorganic materials selected from among metal oxide particle and nitride particle with a particle size of 10 μm or less.

7. The composite particle according to claim 6, wherein the inorganic particle other than silica is one or more inorganic materials selected from among titanium dioxide, magnesium oxide, zinc oxide, alumina and aluminum nitride.

8. A method of producing a composite particle, the method comprising: sintering a mixture of (1) a finely powdered silica having a BET specific surface area of 50 m²/g or greater, (2) an inorganic particle other than silica, and (3) water at a temperature of 300° C. or higher to form a glass-like substance, and then crushing the glass-like substance.

9. A method of producing a spherical composite particle comprising a silica and an inorganic compound particle derived from an inorganic particle and integrated with said silica, the method comprising: melting and spheroidizing a mixture of (1) a finely powdered silica having a BET specific surface area of 50 m²/g or greater, (2) an inorganic particle other than silica, and (3) water in a flame of 1,800° C. or higher.

10. The method of producing a spherical composite particle according to claim 9, further comprising a step, prior to the melting and spheroidizing in a flame, of sintering the mixture at a temperature of 300° C. or higher to form a glass-like substance, and then crushing the glass-like substance.

11. A thermosetting resin composition comprising the composite particle according to claim 1 and a thermosetting resin.

12. The thermosetting resin composition according to claim 11, wherein the thermosetting resin is one or more resins selected from among epoxy resins, silicone resins, silicone-epoxy hybrid resins and cyanate resins.

13. The thermosetting resin composition according to claim 11, wherein the thermosetting resin composition is a white resin composition comprising 50 to 1,200 parts by mass of the spherical composite oxide particle (B) per 100 parts by mass of the thermosetting resin (A).

14. A thermosetting resin composition comprising the spherical composite particle according to claim 4 and a thermosetting resin.

15. The thermosetting resin composition according to claim 14, wherein the thermosetting resin is one or more resins selected from among epoxy resins, silicone resins, silicone-epoxy hybrid resins and cyanate resins.

16. The thermosetting resin composition according to claim 14, wherein the thermosetting resin composition is a white resin composition comprising 50 to 1,200 parts by mass of the spherical composite oxide particle (B) per 100 parts by mass of the thermosetting resin (A).

17. A reflector for a light-emitting semiconductor device, formed from the thermosetting resin composition according to claim 11.

18. A reflector for a light-emitting semiconductor device, formed from the thermosetting resin composition according to claim 14.

19. A light-emitting semiconductor device in which a light-emitting semiconductor element is installed on the reflector for a light-emitting semiconductor device according to claim 17.

20. A light-emitting semiconductor device in which a light-emitting semiconductor element is installed on the reflector for a light-emitting semiconductor device according to claim 18.

21. A light-emitting semiconductor device in which a light-emitting semiconductor element is encapsulated with the thermosetting resin composition according to claim 11.

22. A light-emitting semiconductor device in which a light-emitting semiconductor element is encapsulated with the thermosetting resin composition according to claim 14.
